(19) United States
(12) Patent Application Publication
(10) Pub. No.: US 2024/0022230 A1
(43) Pub. Date: Jan. 18, 2024

(54) PIEZOELECTRIC DEVICE

(71) Applicant: KYOCERA Corporation, Kyoto-shi (JP)

(72) Inventor: Motoharu ANDO, San Diego, CA (US)

(73) Assignee: KYOCERA Corporation, Kyoto-shi (JP)

(21) Appl. No.: 18/473,610

(22) Filed: Sep. 25, 2023

Related U.S. Application Data
(63) Continuation of application No. PCT/JP22/00760, filed on Jan. 12, 2022.

(30) Foreign Application Priority Data
Mar. 26, 2021 (JP) 2021-053180

(51) Int. Cl. H03H 9/09; H03H 9/05; H03H 9/10; H03H 9/19

(52) U.S. Cl. CPC H03H 9/09; H03H 9/0557; H03H 9/1021; H03H 9/19

(57) ABSTRACT

A piezoelectric device includes a piezoelectric element, a package, and a vibration absorber. The package contains at least the piezoelectric element. The vibration absorber is disposed on a mounting component, and supports the package. The mounting component is a component to which the package is mounted. The vibration absorber absorbs vibration transmitted from the mounting component to the package. The piezoelectric element has a substantially rectangular shape in plan view. The piezoelectric element is a crystal resonator element including a crystal strip, and electrodes. The crystal strip includes a first major face and a second major face opposite to the first major face. The electrodes extend from the first major face of the crystal strip to the second major face.

### TECHNICAL FIELD

The present disclosure relates to a piezoelectric device including a piezoelectric element.

### BACKGROUND OF INVENTION

Piezoelectric devices with a piezoelectric element housed within a package are in widespread use. Piezoelectric devices including a piezoelectric element and an electronic element are also in common use. Examples of such piezoelectric devices include a simple packaged crystal oscillator (SPXO), a voltage controlled crystal oscillator (VCXO), a temperature compensated crystal oscillator (TCXO), and an oven controlled crystal oscillator (OCXO).

Other known piezoelectric devices include a piezoelectric element doubly sealed by two packages. For example, Patent Literature 1 discloses a piezoelectric device in which a piezoelectric element and an electronic element are housed within a first package, and in which the first package is further housed within a second package. Patent Literature 2 discloses a piezoelectric device in which a piezoelectric element is housed within a first package, and in which the first package and an electronic element are further housed within a second package. In these types of piezoelectric devices, the first package housing the piezoelectric element is shut off from the surrounding atmosphere by the second package. This helps to reduce the risk that temperature changes in the surrounding atmosphere may propagate and reach the piezoelectric element. This in turn leads to stabilization of oscillation frequency.

### CITATION LIST

### Patent Literature

Patent Literature 1: Japanese Unexamined Patent Application Publication No. 2019-153849
Patent Literature 2: Japanese Unexamined Patent Application Publication No. 2019-153851

### SUMMARY

According to the present disclosure, a piezoelectric device includes a piezoelectric element, a package, and a vibration absorber. The package contains at least the piezoelectric element. The vibration absorber is disposed on a mounting component, and supports the package. The mounting component is a component to which the package is mounted. The vibration absorber absorbs vibration transmitted from the mounting component to the package.

### BRIEF DESCRIPTION OF THE DRAWINGS

FIG. 1 is a perspective view of a piezoelectric device according to Embodiment 1.

FIG. 2 illustrates a cross-section taken along a line II-II in FIG. 1.

FIG. 3 is an exploded perspective view of the piezoelectric device according to Embodiment 1.

FIG. 4 is an exploded perspective view of the interior of a package in the piezoelectric device according to Embodiment 1.

FIG. 5 is a perspective view of a piezoelectric device according to Embodiment 2.

FIG. 6 illustrates a cross-section taken along a line VI-VI in FIG. 5.

FIG. 7 is an exploded perspective view of the piezoelectric device according to Embodiment 2.

FIG. 8 is an exploded perspective view of the interior of a first package in the piezoelectric device according to Embodiment 2.

FIG. 9 is a cross-sectional view of a piezoelectric device according to Embodiment 3.

FIG. 10 is a cross-sectional view of a piezoelectric device according to Embodiment 4.

FIG. 11 is a cross-sectional view of a piezoelectric device according to Embodiment 5.

FIG. 12 is a cross-sectional view of a piezoelectric device according to Embodiment 6.

### DESCRIPTION OF EMBODIMENTS

Modes for implementing the present disclosure (to be referred to as “embodiments” hereinafter) are described below with reference to the attached drawings. In the specification and the drawings, substantially identical components are designated by the same reference signs to avoid repetitive descriptions. Various shapes in the drawings are illustrated with priority given to ease of illustration and description, and thus not necessarily to scale in terms of dimensions and proportions.

### Embodiment 1

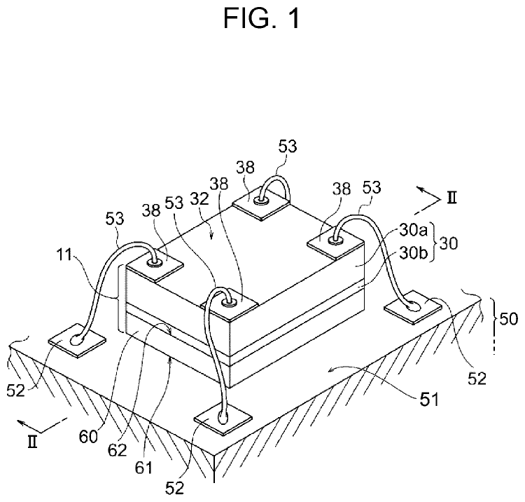

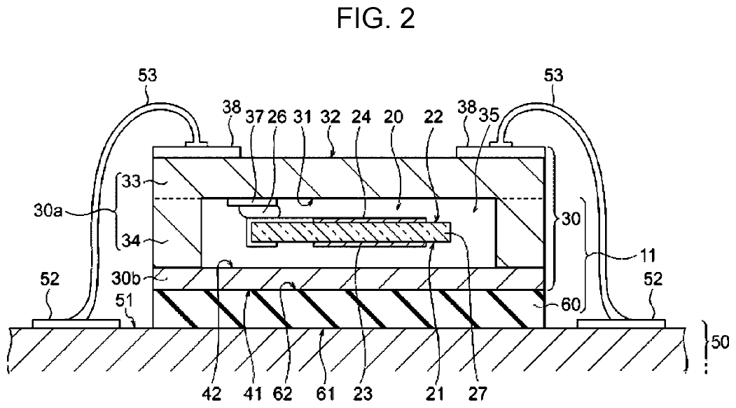

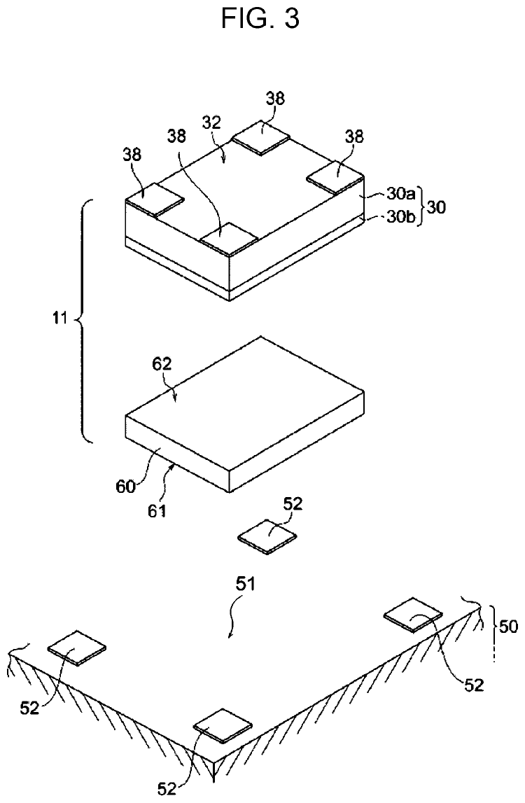

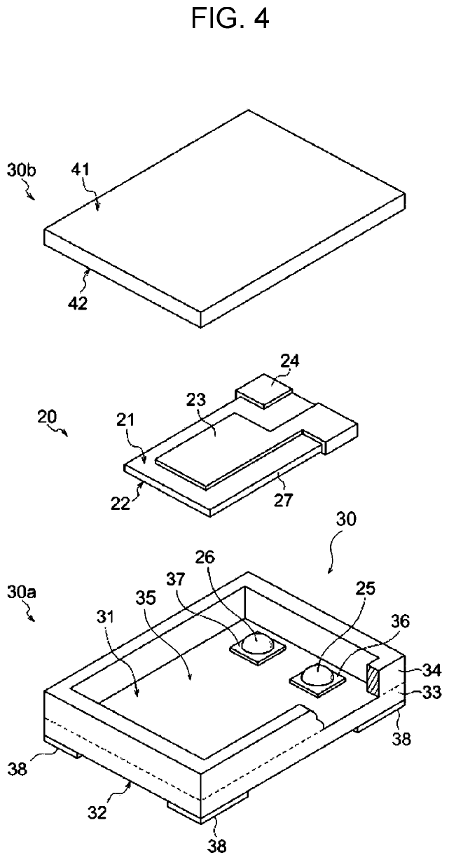

A piezoelectric device 11 according to Embodiment 1 is described below with reference to FIGS. 1 to 4. In FIGS. 1 and 3, a mounting component 50 is illustrated in partial cutaway view. In FIG. 4, a base 30a is illustrated in partial cutaway view. The internal structural features (such as a piezoelectric element 20) of a package 30 is illustrated only in FIGS. 2 and 4.

The piezoelectric device 11 includes the piezoelectric element 20, the package 30, and a vibration absorber 60. The package 30 contains at least the piezoelectric element 20. The vibration absorber 60 is disposed on a mounting component 50, and supports the package 30. The mounting component 50 is a component to which the package 30 is mounted. The vibration absorber 60 absorbs vibration transmitted from the mounting component 50 to the package 30.

The piezoelectric element 20 has a substantially rectangular shape when viewed in plan. The piezoelectric element 20 is a crystal resonator element including a crystal strip 27, and electrodes 23 and 24. The crystal strip 27 includes a first major face 21 and a second major face 22 opposite to the first major face 21. The electrodes 23 and 24 extend from the first major face 21 of the crystal strip 27 to the second major face 22. The crystal strip 27 is, for example, an AT-cut plate. The electrodes 23 and 24 are insulated from each other. The electrodes 23 and 24 are each divided into an excitation electrode, an extended electrode, a pad electrode, and other electrode portions. The electrodes 23 and 24 extend from the first major face 21 to the second major face 22 across a lateral face of the crystal strip 27.

Now, an alternating voltage is applied to the crystal strip 27 via the electrodes 23 and 24. This causes the crystal strip 27 to vibrate in thickness shear mode such that the first major face 21 and the second major face 22 are displaced relative to each other. A specific oscillation frequency is thus generated. As described above, the piezoelectric element 20 is operable to, based on the piezoelectric and inverse piezoelectric effects of the crystal strip 27, output a signal with a predetermined oscillation frequency.

Although a thickness shear mode resonator element is used as the piezoelectric element 20, instead of a thickness shear mode resonator element, a tuning-fork flexural mode resonator element, a contour shear mode resonator element, or the like may be used. Instead of a crystal resonator element, a piezoelectric element made of a ceramic material or other material may be used. The piezoelectric element 20 may have any two-dimensional shape other than a rectangle. For example, the piezoelectric element 20 may have a two-dimensional shape such as a circle, an ellipse, or a polygon.

The package 30 includes a base 30a, and a lid 30b. The piezoelectric element 20 is mounted to the base 30a. The lid 30b hermetically seals the piezoelectric element 20 when joined to the base 30a. Although the package 30 according to Embodiment 1 is a piezoelectric resonator, the package 30 may be an SPXO, a VCXO, a TCXO, or an OCXO. The package 30 may have any three-dimensional shape other than a cuboid, for example, a circular cylinder or an elliptic cylinder.

The base 30a includes a substrate part 33, and a frame part 34. The piezoelectric element 20 is mounted to the substrate part 33. The frame part 34 is located on a peripheral edge of the substrate part 33. The substrate part 33 includes a first major face 31, a second major face 32, a pair of piezoelectric-element-mounting pads 36 and 37, and external terminals 38. The first major face 31 and the second major face 32 are located opposite from each other. The piezoelectric-element-mounting pads 36 and 37 are disposed on the first major face 31. Each of the external terminals 38 is disposed at a respective one of the four corners of the second major face 32. The frame part 34 is in the form of a rectangular frame disposed on the peripheral edge of the first major face 31 of the substrate part 33. The interior of the package 30 defines a recessed space 35. The recessed space 35 is bounded by the substrate part 33 and the frame part 34. The electrodes 23 and 24 of the piezoelectric element 20 are electrically connected to the piezoelectric-element-mounting pads 36 and 37 by use of joining materials 25 and 26 such as electrically conductive adhesive, respectively.

The substrate part 33 and the frame part 34 each consist of, for example, a multilayer ceramic plate including multiple green sheets that have been stacked together and fired. Each of the piezoelectric-element-mounting pads 36 and 37, and each of the external terminals 38 are electrically interconnected by means of internal wiring (not illustrated) that is provided in the substrate part 33 and the frame part 34. The internal wiring consists of, for example, a conductor pattern or a via-hole conductor printed on the green sheets. The piezoelectric-element-mounting pads 36 and 37, and the external terminals 38 each consist of, for example, a gold (Au) layer on its surface, and the underlying nickel (Ni) layer.

The lid 30b is in the form of a rectangular flat plate. The lid 30b includes a first major face 41 and a second major face 42 opposite to the first major face 41. The lid 30b is made of, for example, a metal such as Kovar, or a ceramic material. The lid 30b is joined to the base 30a by electric welding, glass sealing, or other methods to hermetically seal the recessed space 35. The lid 30b and the external terminals 38 are electrically connected by means of internal wiring (not illustrated) that is provided in the substrate part 33 and the frame part 34.

The mounting component 50 is a component within an electronic apparatus to which the piezoelectric device 11 is to be mounted. The mounting component 50 includes a major face 51, and package-mounting pads 52. An example of the mounting component 50 is a printed wiring board. The printed wiring board includes a land and a wiring pattern (not illustrated) that are made of copper foil or other materials and disposed on a synthetic resin substrate. Each of the package-mounting pads 52 is disposed on the major face 51 at a location corresponding to a respective one of the external terminals 38 of the package 30. Each of the package-mounting pads 52 is electrically connected to a respective one of the external terminals 38 by a wire 53. The wire 53 is made of, for example, a metal such as gold or aluminum. The wire 53 has flexibility. The wire 53 is connected by the common wire bonding technique. The package-mounting pads 52 are each electrically connected to a predetermined location by a wiring pattern (not illustrated) that is provided on the major face 51, inside the mounting component 50, or on the back side of the mounting component 50. The mounting component 50 may be a multilayer ceramic plate, or the like.

The vibration absorber 60 is in the form of a rectangular flat plate. The vibration absorber includes a first major face 61 and a second major face 62 opposite to the first face 61. The vibration absorber 60 may be made of any material capable of absorbing vibration transmitted from the mounting component 50 to the package 30. One suitable example of such a material is a gel material, in particular, silicone gel (polymeric gel composition). Silicone gel is a moderately soft gel material mainly made of silicone. For example, such silicone gel is commercially available under the name αGEL (registered trademark). If the vibration absorber 60 is made of silicone gel, the silicone gel is formed into a rectangular flat sheet, the second major face 62 is secured via an adhesive to the package 30, and the first major face 61 is secured via an adhesive to the mounting component 50. A suitable example of such an adhesive is an acrylic pressure sensitive adhesive. The vibration absorber 60 may have any two-dimensional shape other than a rectangle. For example, the vibration absorber 60 may have a two-dimensional shape such as a circle, an ellipse, or a polygon. The number of vibration absorbers 60 is not limited to one. Multiple vibration absorbers 60 may be provided.

A method for assembling the piezoelectric device 11 is now described below.

First, as illustrated in FIG. 4, the joining materials 25 and 26 consisting of electrically conductive adhesive are respectively applied to the piezoelectric-element-mounting pads 36 and 37 on the first major face 31 of the substrate part 33. The electrodes 23 and 24 of the piezoelectric element 20 are then respectively placed on the joining materials 25 and 26, and subjected to heat treatment at a predetermined temperature for a predetermined time. This causes the joining materials 25 and 26 to cure. As a result, the piezoelectric element 20 is secured in a cantilever fashion over the substrate part 33. The recessed space 35 of the base 30a is then sealed with the lid 30b. The package 30 is thus completed.

Subsequently, as illustrated in FIG. 3, the package 30 is turned upside down (such that the lid 30b is facing downward) from the state illustrated in FIG. 4 (in which the lid 30b is facing upward). The package 30 is then secured onto the major face 51 of the mounting component 50 with the vibration absorber 60 interposed therebetween.

Lastly, as illustrated in FIG. 1, each of the external terminals 38 of the package 30 is connected by the wire 53 to a respective one of the package-mounting pads 52 of the mounting component 50. The piezoelectric device 11 is thus mounted onto the mounting component 50.

Operation and effects of the piezoelectric device 11 are now described below. The present inventor has conducted repeated experiments and analyses with a view to further stabilization of the oscillation frequency of the piezoelectric device. As a result, the inventor has found out that minute vibrations (e.g., vibrations due to an airflow generated by the cooling fan, or vibrations of the cooling fan) from the mounting component (e.g., the printed wiring board) have an influence on the oscillation frequency of the piezoelectric device. This influence is presumed to be due to the direct piezoelectric effect (generation of voltage due to applied pressure) possessed by the piezoelectric element. The present disclosure is based on the above finding. That is, the vibration absorber 60 is inserted between the mounting component 50 and the package 30. Vibration of the mounting component 50 is thus absorbed by the vibration absorber 60. This helps to reduce vibration transmitted from the mounting component 50 to the package 30. The above-mentioned configuration of the piezoelectric device 11 therefore makes it possible to achieve further stabilization of oscillation frequency.

### Embodiment 2

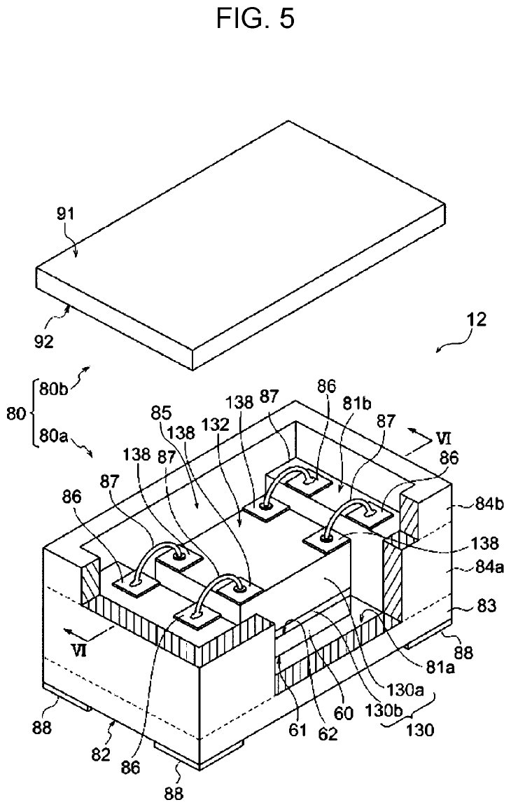

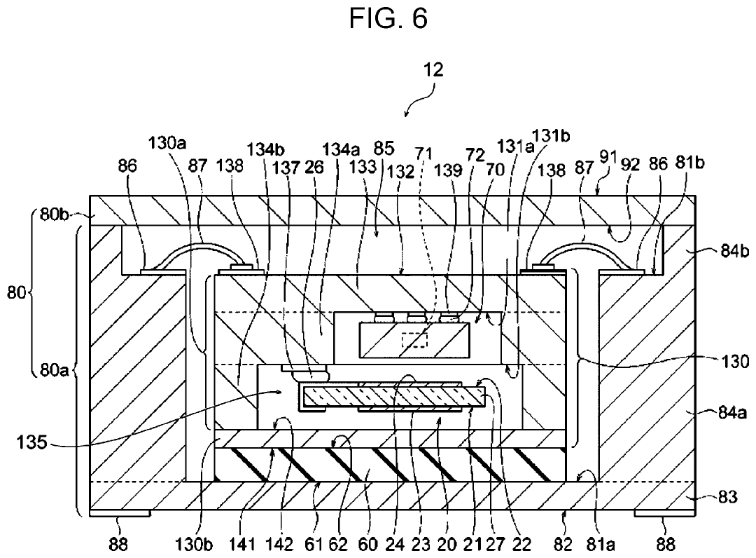

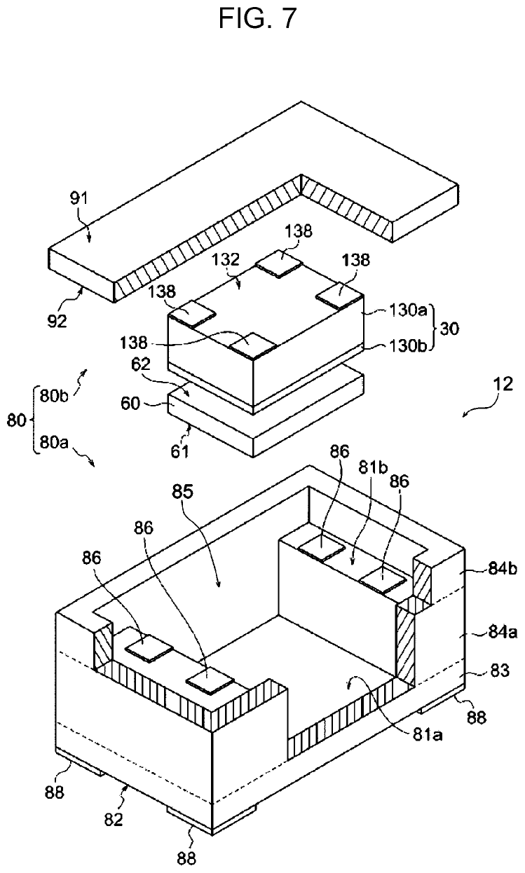

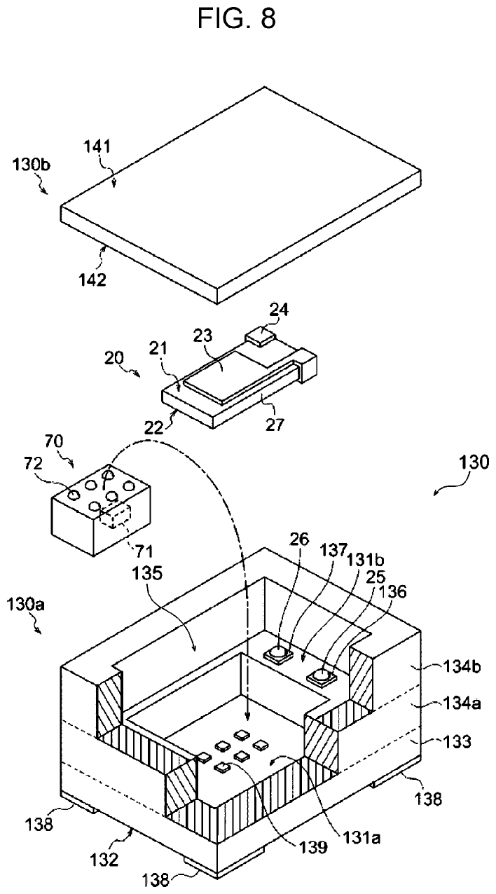

A piezoelectric device 12 according to Embodiment 2 is described below with reference to FIGS. 5 to 8. In FIG. 5, the piezoelectric device 12 prior to joining of a lid 80b to a base 80a is illustrated with the base 80a in partial cutaway view. In FIG. 7, the lid 80b and the base 80a are illustrated in partial cutaway view. In FIG. 8, a base 130a is illustrated in partial cutaway view. The internal structural features (such as a piezoelectric element 20) of a first package 130 is illustrated only in FIGS. 6 and 8.

The piezoelectric device 12 includes the piezoelectric element 20, an electronic element the first package 130, a second package 80, and a vibration absorber 60. The electronic element drives the piezoelectric element 20. The first package 130 contains the piezoelectric element 20 and the electronic element 70. The second package 80 further contains the first package 130. The vibration absorber 60 is disposed inside the second package 80, and supports the first package 130. The vibration absorber 60 absorbs vibration transmitted from the second package 80 to the first package 130. Hereinafter, differences from Embodiment 1 are mainly described. The piezoelectric element 20 is the same as, and/or similar to, the piezoelectric element according to Embodiment 1, and thus not described below in further detail.

The first package 130 includes the base 130a, and a lid 130b. The electronic element 70 and the piezoelectric element 20 are mounted to the base 130a. The lid 130b hermetically seals the electronic element 70 and the piezoelectric element 20 when joined to the base 130a. Although the first package 130 according to Embodiment 2 is a TCXO, the first package 130 may be a VCXO, an OCXO, or the like. The first package 130 and the second package 80 may have any three-dimensional shape other than a cuboid, for example, a circular cylinder or an elliptic cylinder.

The base 130a includes a substrate part 133, a first frame part 134a, and a second frame part 134b. The electronic element 70 is mounted to the substrate part 133. The first frame part 134a is located on the peripheral edge of the substrate part 133. The piezoelectric element 20 is mounted to the first frame part 134a. The second frame part 134b is located on the peripheral edge of the first frame part 134a. The substrate part 133 includes a first major face 131a, a second major face 132, multiple electronic-element-mounting pads 139, and external terminals 138. The first major face 131a and the second major face 132 are located opposite from each other. The electronic-element-mounting pads 139 are disposed on the first major face 131a. Each of the external terminals 138 is disposed at a respective one of the four corners of the second major face 132. The first frame part 134a includes a major face 131b, and a pair of piezoelectric-element-mounting pads 136 and 137 disposed on the major face 131b. The first frame part 134a is disposed in the form of a rectangular frame on the peripheral edge of the first major face 131a of the substrate part 133. The second frame part 134b is disposed in the form of a rectangular frame on the peripheral edge of the major face 131b of the first frame part 134a. The interior of the first package 130 defines a recessed space 135. The recessed space 135 is bounded by the substrate part 133, the first frame part 134a, and the second frame part 134b. The electrodes 23 and 24 of the piezoelectric element 20 are electrically connected to the piezoelectric-element-mounting pads 136 and 137 by use of joining materials 25 and 26 such as electrically conductive adhesive, respectively.

The substrate part 133, the first frame part 134a, and the second frame part 134b each consist of, for example, a multilayer ceramic plate including multiple green sheets that have been stacked together and fired. The piezoelectric-element-mounting pads 136 and 137, the external terminals 138, and the electronic-component-mounting pads 139 are electrically interconnected by means of internal wiring (not illustrated) that is provided in the substrate part 133, the first frame part 134a, and the second frame part 134b. The internal wiring consists of, for example, a conductor pattern or a via-hole conductor printed on the green sheets. The piezoelectric-element-mounting pads 136 and 137, the external terminals 138, and the electronic-element-mounting pads 139 each consist of, for example, an Au layer on its surface, and the underlying Ni layer.

The lid 130b is in the form of a rectangular flat plate. The lid 130b includes a first major face 141 and a second major face 142 opposite to the first major face 141. The lid 130b is made of, for example, a metal such as Kovar, or a ceramic material. The lid 130b is joined to the base 130a by electric welding, glass sealing, or other methods to hermetically seal the recessed space 135. The lid 130b and the external terminals 138 are electrically connected by means of internal wiring (not illustrated) that is provided in the substrate part 133, the first frame part 134a, and the second frame part 134b.

The electronic element 70 is an IC (Integrated Circuit) including the functionality of a temperature sensor 71 and the functionality of, for example, an oscillation circuit for the piezoelectric element 20. Further, the electronic element 70 is a flip chip (FC) with connection terminals 72 in the form of bumps. The bumps are made of, for example, gold or solder. Each of the bumps is electrically connected to a respective one of the electronic-element-mounting pads 139. The number of connection terminals 72 provided is the same as the number of electronic-element-mounting pads 139 provided. That is, the electronic element 70 is mounted to the base 130a via the connection terminals 72, with a circuit face of the electronic element 70 facing the electronic-element-mounting pads 139 on the first major face 131a, that is, with the circuit face facing down. The circuit face of the electronic element 70 is a face provided with a circuit and including the connection terminals 72. The temperature sensor 71 utilizes, for example, the forward voltage of a p-n junction formed inside the IC. The forward voltage of the p-n junction decreases with increasing temperature. Accordingly, voltage information can be obtained by measuring the forward voltage with a constant current being passed through the p-n junction. Temperature information on the electronic element 70 and, by extension, the piezoelectric element 20 can be obtained by conversion from the obtained voltage information. The electronic element 70 may be, for example, a thermistor, a diode, or the like consisting solely of a temperature sensor. The electronic element 70 is not limited to an FC but may be a resin molded component or a packaged component. The connection terminals 72 to be used may be wires made of a material such as aluminum or gold, instead of bumps.

The second package 80 includes the base 80a, and the lid 80b. The first package 130 is mounted to the base 80a. The lid 80b hermetically seals the first package 130 when joined to the base 80a.

The base 80a includes a substrate part 83, a first frame part 84a, and a second frame part 84b. The first package 130 is mounted to the substrate part 83. The first frame part 84a is located on the peripheral edge of the substrate part 83. The second frame part 84b is located on the peripheral edge of the first frame part 84a. The substrate part 83 includes a first major face 81a, a second major face 82, and external terminals 88. The first major face 81a and the second major face 82 are located opposite from each other. Each of the external terminals 88 is disposed at a respective one of the four corners of the second major face 82. The first frame part 84a includes a major face 81b, and package-mounting pads 86 disposed on the major face 81b. The first frame part 84a is disposed in the form of a rectangular frame on the peripheral edge of the first major face 81a of the substrate part 83. The second frame part 84b is disposed in the form of a rectangular frame on the peripheral edge of the major face 81b of the first frame part 84a. The interior of the second package 80 defines a recessed space 85. The recessed space 85 is bounded by the substrate part 83, the first frame part 84a, and the second frame part 84b. Each of the external terminals 138 of the first package 130, and a respective one of the package-mounting pads 86 are electrically connected by a wire 87. The wire 87 is made of, for example, a metal such as gold or aluminum. The wire 87 has flexibility. The wire 87 is connected by the common wire bonding technique.

The substrate part 83, the first frame part 84a, and the second frame part 84b each consist of, for example, a multilayer ceramic plate including multiple green sheets that have been stacked together and fired. Each of the package-mounting pads 86, and a respective one of the external terminals 88 are electrically interconnected by means of internal wiring (not illustrated) that is provided in the substrate part 83, the first frame part 84a, and the second frame part 84b. The internal wiring consists of, for example, a conductor pattern or a via-hole conductor printed on the green sheets. The package-mounting pads 86 and the external terminals 88 each consist of, for example, an Au layer on its surface, and the underlying Ni layer.

The lid 80b is in the form of a rectangular flat plate. The lid 80b includes a first major face 91 and a second major face 92 opposite to the first major face 91. The lid 80b is made of, for example, a metal such as Kovar, or a ceramic material. The lid 80b is joined to the base 80a by electric welding, glass sealing, or other methods to hermetically seal the recessed space 85. The lid 80b and the external terminals 88 are electrically connected by means of internal wiring (not illustrated) that is provided in the substrate part 83, the first frame part 84a, and the second frame part 84b.

The vibration absorber 60 is the same as, and/or similar to, the vibration absorber according to Embodiment 1. The vibration absorber 60 includes a first major face 61, and a second major face 62. The first major face 61 is secured via an adhesive to the first major face 81a of the second package 80. The second major face 62 is secured via an adhesive to the first package 130.

A method for assembling the piezoelectric device 12 is now described below.

First, as illustrated in FIG. 8, a face of the electronic element 70 provided with the connection terminals 72 is positioned to face the first major face 131a within the recessed space 135. With the connection terminals 72 aligned with the electronic-element-mounting pads 139, the connection terminals 72 are pressed against the electronic-element-mounting pads 139 under application of heat or ultrasonic waves. As a result, the connection terminals 72 are joined to the electronic-element-mounting pads 139, and the electronic element 70 is thus mounted inside the first package 130.

Subsequently, the joining materials 25 and 26 consisting of electrically conductive adhesive are respectively applied to the piezoelectric-element-mounting pads 136 and 137 on the major face 131b of the first frame part 134a. The electrodes 23 and 24 of the piezoelectric element 20 are then respectively placed on the joining materials 25 and 26, and subjected to heat treatment at a predetermined temperature for a predetermined time. This causes the joining materials 25 and 26 to cure. As a result, the piezoelectric element 20 is secured in a cantilevered fashion over the first frame part 134a. The piezoelectric element 20 is thus mounted inside the first package 130.

The recessed space 135 of the base 130a is then sealed with the lid 130b. The first package 130 is thus completed.

Subsequently, as illustrated in FIG. 7, the first package 130 is turned upside down (such that the lid 130b is facing downward) from the state illustrated in FIG. 8 (in which the lid 130b is facing upward). The first package 130 is then secured over the first major face 81a of the second package 80 with the vibration absorber 60 interposed therebetween.

Subsequently, as illustrated in FIG. 5, each of the external terminals 138 of the first package 130 is connected by the wire 87 to a respective one of the package-mounting pads 86 of the second package 80. The first package 130 is thus mounted inside the second package 80.

Lastly, the recessed space 85 of the second package 80 is sealed with the lid 80b. The piezoelectric device 12 is thus completed.

To mount the piezoelectric device 12 configured as described above to a surface of a printed wiring board of an electronic apparatus, the bottom face of the external terminals 88 is secured to the printed wiring board by means of solder, Au bumps, an electrically conductive adhesive, or the like. The piezoelectric device 12 serves as an oscillation source in, for example, various electronic apparatuses such as personal computers, clocks, gaming consoles, communication apparatuses, or vehicle-mounted apparatuses such as car navigation systems.

Operation and effects of the piezoelectric device 12 are now described below.

In the piezoelectric device 12, the piezoelectric element 20 and the electronic element 70 are housed within the first package 130, and the first package 130 is further housed within the second package 80. According to the above-mentioned structure of the piezoelectric device 12, the first package 130 housing the piezoelectric element 20 and the electronic element 70 is shut off from the surrounding atmosphere by the second package 80. This helps to reduce the risk that temperature changes in the surrounding atmosphere may propagate and reach the piezoelectric element 20 and the electronic element 70. This in turn leads to stabilization of oscillation frequency.

Additionally, the vibration absorber 60 is inserted between the second package 80 and the first package 130. Vibration of the second package 80 is thus absorbed by the vibration absorber 60. This helps to reduce vibration transmitted from the second package 80 to the first package 130. The above-mentioned configuration of the piezoelectric device 12, coupled with the effects mentioned above, therefore makes it possible to achieve further stabilization of oscillation frequency. The effects of the configuration of the piezoelectric device 12 are particularly pronounced with respect to abrupt temperature changes and vibrations caused by an airflow generated by a cooling fan. Embodiment 2 is otherwise the same, and/or similar to, Embodiment 1 in configuration, operation, and effects.

### Embodiment 3

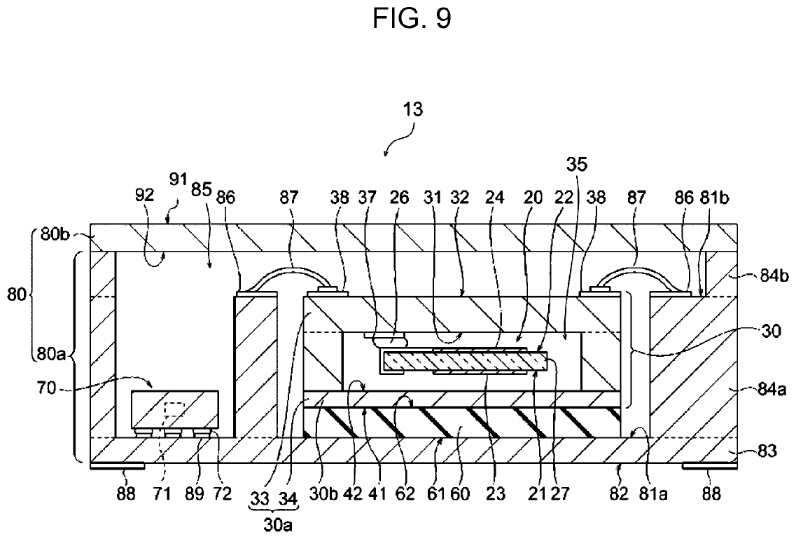

A piezoelectric device 13 according to Embodiment 3 is described below with reference to FIG. 9. FIG. 9 illustrates a cross-section corresponding to the cross-sections illustrated in FIGS. 2 and 6. As is apparent from the correspondence between features of these cross-sections, the piezoelectric device 13 according to Embodiment 3 shares many common features with the piezoelectric device 11 according to Embodiment 1 (FIG. 2) and the piezoelectric device 12 according to Embodiment 2 (FIG. 6). Accordingly, a first package 30 is designated by using the same reference sign as that used for the package 30 according to Embodiment 1 (FIG. 2), and a second package 80 is designated by using the same reference sign as that used for the second package 80 according to Embodiment 2 (FIG. 6).

The piezoelectric device 13 includes a piezoelectric element 20, an electronic element 70, the first package 30, the second package 80, and a vibration absorber 60. The first package 30 contains the piezoelectric element 20. The electronic element 70 drives the piezoelectric element 20. The second package 80 further contains the electronic element 70 and the first package 30. The vibration absorber 60 is disposed inside the second package 80, and supports the first package 30. The vibration absorber 60 absorbs vibration transmitted from the second package 80 to the first package 30.

The first package 30 includes a first base 30a, and a first lid 30b. The piezoelectric element is mounted to the first base 30a. The first lid 30b hermetically seals the piezoelectric element together with the first base 30a. The second package 80 includes a second base 80a, and a second lid 80b. The electronic element 70 is mounted to the second base 80a. The first package 30 is mounted to the second base 80a with the vibration absorber 60 interposed therebetween. The second lid 80b hermetically seals the electronic element 70 and the first package 30 together with the second base 80a.

The piezoelectric device 13 differs from the piezoelectric device 12 according to Embodiment 2 (FIG. 6) in that the electronic element 70 is mounted not inside the first package but to a first major face 81a of the second package 80. According to Embodiment 3, electronic-element-mounting pads 89 are provided on the first major face 81, and the electronic element 70 and the first package 30 are disposed side by side over the first major face 81a.

According to the configuration of the piezoelectric device 13 described above, the electronic element 70 and the first package 30 are disposed side by side over the first major face 81a. This means that the condition of heat conduction through the first major face 81a is the same between the electronic element 70 and the first package 30. This allows the temperature sensor 71 inside the electronic element 70 to measure the temperature of the piezoelectric element 20 inside the first package 30 with improved accuracy, leading to improved accuracy of temperature compensation. Embodiment 3 is otherwise the same, and/or similar to, Embodiments 1 and 2 in configuration, operation, and effects. The above-mentioned configuration of the piezoelectric device 13, coupled with the effects mentioned above, therefore makes it possible to achieve even further stabilization of oscillation frequency.

### Embodiment 4

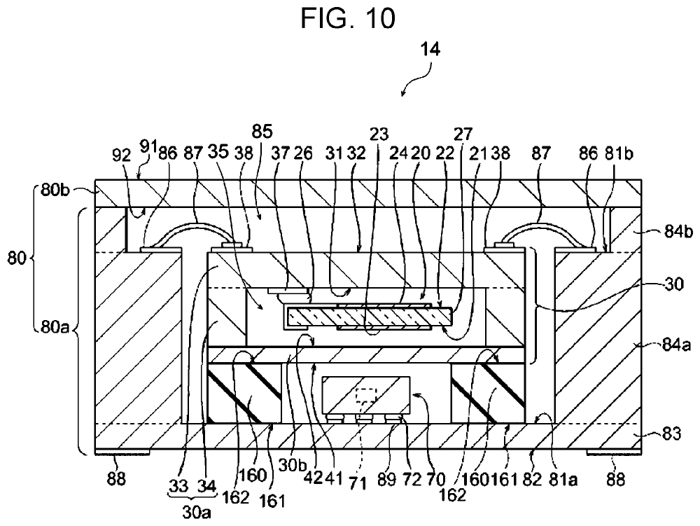

A piezoelectric device 14 according to Embodiment 4 is described below with reference to FIG. 10. As with Embodiment 3, in Embodiment 4, a first package 30 is designated by using the same reference sign as that used for the package 30 according to Embodiment 1 (FIG. 2), and a second package 80 is designated by using the same reference sign as that used for the second package 80 according to Embodiment 2 (FIG. 6).

The piezoelectric device 14 includes a piezoelectric element 20, an electronic element 70, the first package 30, the second package 80, and a vibration absorber 160. The first package 30 contains the piezoelectric element 20. The electronic element 70 drives the piezoelectric element 20. The second package 80 further contains the electronic element 70 and the first package 30. The vibration absorber 160 is disposed inside the second package 80, and supports the first package 30. The vibration absorber 160 absorbs vibration transmitted from the second package 80 to the first package 30.

The first package 30 includes a first base 30a, and a first lid 30b. The piezoelectric element is mounted to the first base 30a. The first lid 30b hermetically seals the piezoelectric element together with the first base 30a. The second package 80 includes a second base 80a, and a second lid 80b. The electronic element 70 is mounted to the second base 80a. The first package 30 is mounted to the second base 80a with the vibration absorber 160 interposed therebetween. The second lid 80b hermetically seals the electronic element 70 and the first package 30 together with the second base 80a.

The piezoelectric device 14 differs from the piezoelectric device 12 according to Embodiment 3 (FIG. 9) in that when viewed in plan, the electronic element 70 and the first package overlap each other. When viewed in plan, the vibration absorber 160 is divided into two parts along two opposite edges of the first package 30. The vibration absorber 60 includes a first major face 161, and a second major face 162. The first major face 161 is secured via an adhesive to the first major face 81a of the second package 80. The second major face 162 is secured via an adhesive to the first package 30. The vibration absorber 160 has a height greater than the height of the electronic element 70 mounted to the first major face 81a. This allows the electronic element 70 to be inserted between the pair of vibration absorbers 160. The material or other features of the vibration absorber 160 are the same as, and/or similar to, those of the vibration absorber according to Embodiment 1. When viewed in plan, the vibration absorber 160 may be disposed at each of the four corners of the first package 30.

According to the configuration of the piezoelectric device 14 described above, when view in plan, the electronic element 70 and the first package 30 overlap each other. This allows for reduced area occupied by the piezoelectric device 14, which contributes to miniaturization of an electronic apparatus into which the piezoelectric device 14 is to be incorporated. Embodiment 4 is otherwise the same, and/or similar to, Embodiments 1 to 3 in configuration, operation, and effects.

### Embodiment 5

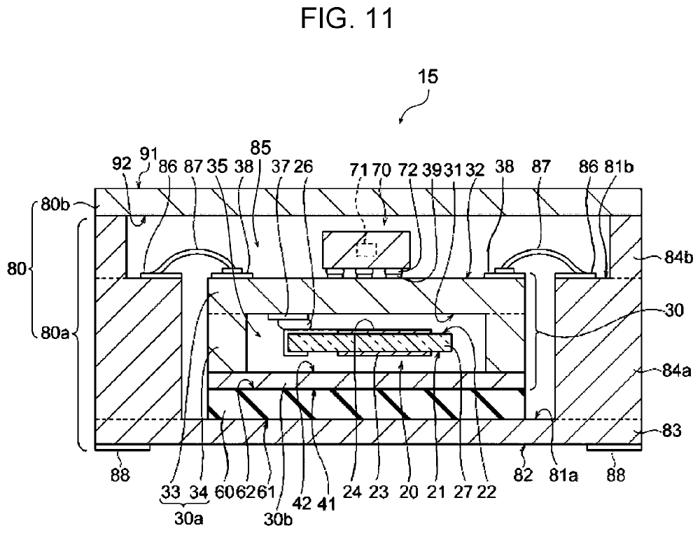

A piezoelectric device 15 according to Embodiment 5 is described below with reference to FIG. 11. As with Embodiment 3, in Embodiment 5, a first package 30 is designated by using the same reference sign as that used for the package 30 according to Embodiment 1 (FIG. 2), and a second package 80 is designated by using the same reference sign as that used for the second package 80 according to Embodiment 2 (FIG. 6).

The piezoelectric device 15 includes a piezoelectric element 20, an electronic element 70, the first package 30, the second package 80, and a vibration absorber 60. The first package 30 contains the piezoelectric element 20. The electronic element 70 drives the piezoelectric element 20. The second package 80 further contains the electronic element 70 and the first package 30. The vibration absorber 60 is disposed inside the second package 80, and supports the first package 30. The vibration absorber 60 absorbs vibration transmitted from the second package 80 to the first package 30.

The first package 30 includes a first base 30a, and a first lid 30b. The first base 30a includes a first major face 31 and a second major face 32 opposite to the first major face 31. The piezoelectric element 20 is mounted to the first major face 31. The electronic element 70 is mounted to the second major face 32. The first lid 30b hermetically seals the piezoelectric element together with the first base 30a. The second package 80 includes a second base 80a, and a second lid 80b. The first package 30 is mounted to the second base 80a with the vibration absorber interposed therebetween. The second lid 80b hermetically seals the electronic element 70 and the first package 30 together with the second base 80a. Connection terminals 72 of the electronic element 70 are each electrically connected to a respective one of electronic-component-mounting pads 39 disposed on the second major face 32 of the first base 30a.

The piezoelectric device 15 differs from the piezoelectric device 14 according to Embodiment 4 (FIG. 10) in that the piezoelectric element 20 is mounted to the first major face 31 of the first package 30, and the electronic element 70 is mounted to the second major face 32 of the first package 30. The vibration absorber 60 is the same as, and/or similar to, the vibration absorber according to Embodiment 1. The vibration absorber 60 includes a first major face 61, and a second major face 62. The first major face 61 is secured via an adhesive to the first major face 81a of the second package 80. The second major face 62 is secured via an adhesive to the first package 30.

In the piezoelectric device 15, the electronic element 70 is mounted to the first package supported by the vibration absorber 60. As a result, the vibration absorber 60 serves to reduce not only vibration transmitted from the second package 80 to the first package 30, but also vibration transmitted from the first package 30 to the electronic element 70. The above-mentioned configuration of the piezoelectric device 15 therefore makes it possible to reduce malfunction of the electronic element 70, and also extend the life of the electronic element 70. These effects combine to achieve further stabilization of oscillation frequency. Embodiment 5 is otherwise the same, and/or similar to, Embodiments 1 to 4 in configuration, operation, and effects.

### Embodiment 6

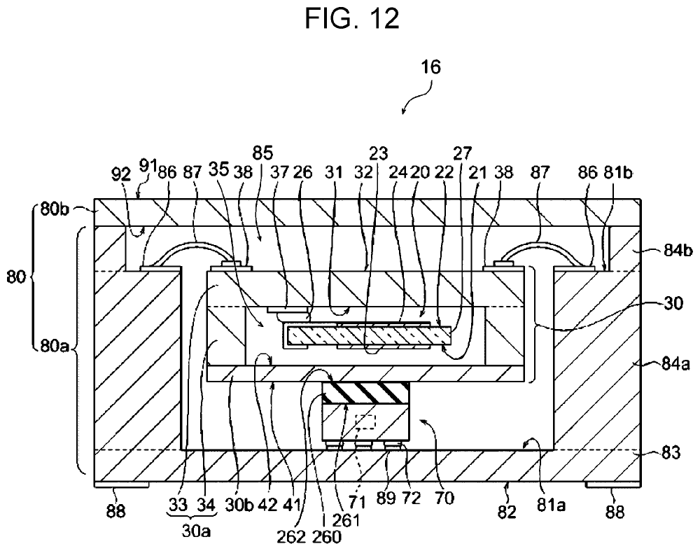

A piezoelectric device 16 according to Embodiment 6 is described below with reference to FIG. 12. As with Embodiment 3, in Embodiment 6, a first package 30 is designated by using the same reference sign as that used for the package 30 according to Embodiment 1 (FIG. 2), and a second package 80 is designated by using the same reference sign as that used for the second package 80 according to Embodiment 2 (FIG. 6).

The piezoelectric device 16 includes a piezoelectric element 20, an electronic element 70, the first package 30, the second package 80, and a vibration absorber 260. The first package 30 contains the piezoelectric element 20. The electronic element 70 drives the piezoelectric element 20. The second package 80 further contains the electronic element 70 and the first package 30. The vibration absorber 260 is disposed inside the second package 80, and supports the first package 30. The vibration absorber 260 absorbs vibration transmitted from the second package 80 to the first package 30.

The first package 30 includes a first base 30a, and a first lid 30b. The piezoelectric element is mounted to the first base 30a. The first lid 30b hermetically seals the piezoelectric element together with the first base 30a. The second package 80 includes a second base 80a, and a second lid 80b. The electronic element 70 with the first package 30 secured thereto with the vibration absorber 260 interposed therebetween is mounted to the second base 80a. The second lid hermetically seals the electronic element 70 and the first package 30 together with the second base 80a. The vibration absorber 260 includes a first major face 261, and a second major face 262. The first major face 261 is secured via an adhesive to the electronic element 70. The second major face 262 is secured via an adhesive to the first package 30. The material or other features of the vibration absorber 260 are the same as, and/or similar to, those of the vibration absorber according to Embodiment 1.

The piezoelectric device 16 differs from the piezoelectric device 14 according to Embodiment 3 (FIG. 9) in that the vibration absorber 260 is disposed between the first package 30 and the electronic element 70, rather than between the first package 30 and the first major face 81a. According to the configuration of the piezoelectric device 16 described above, the electronic element 70 and the vibration absorber 60 are inserted between the second package 80 and the first package 130. As a result, vibration of the second package 80 is damped in the electronic element before being absorbed by the vibration absorber 260. This helps to further reduce vibration transmitted from the second package 80 to the first package 130. The above-mentioned configuration of the piezoelectric device 16 therefore makes it possible to achieve further stabilization of oscillation frequency. Embodiment 6 is otherwise the same, and/or similar to, Embodiments 1 to 4 in configuration, operation, and effects.

### Other Remarks

Although the present disclosure has been described above with reference to the above embodiments, these embodiments are not intended to be limiting of the present disclosure. Various variations as may occur to those skilled in the art can be made to the details of the features of the present disclosure. The present disclosure also encompasses any suitable combinations of some or all of the features of the above embodiments.

### INDUSTRIAL APPLICABILITY

The present disclosure is applicable to piezoelectric devices.

### REFERENCE SIGNS

11, 12, 13, 14, 15, 16 piezoelectric device
20 piezoelectric element
21 first major face
22 second major face
23, 24 electrode
26 joining material
27 crystal strip
30 package (first package)
30a base (first base)
31 first major face
32 second major face
33 substrate part
34 frame part
35 recessed space
36, 37 piezoelectric-element-mounting pad
38 external terminal
39 electronic-element-mounting pad
30b lid (first lid)
41 first major face
42 second major face
50 mounting component
51 major face
52 package-mounting pad
53 wire
160, 260 vibration absorber
61, 161, 261 first major face
62, 162, 262 second major face
70 electronic element
71 temperature sensor
72 connection terminal
80 second package
80a base (second base)
81a first major face
81b major face
82 second major face
83 substrate part
84a first frame part
84b second frame part
85 recessed space
86 package-mounting pad
87 wire
88 external terminal
89 electronic-element-mounting pad
80b lid (second lid)
91 first major face
92 second major face
130 first package
130a base
131a first major face
131b major face
132 second major face
133 substrate part
134a first frame part
134b second frame part
135 recessed space
136, 137 piezoelectric-element-mounting pad
138 external terminal
139 electronic-element-mounting pad
130b lid
141 first major face
142 second major face

1. A piezoelectric device comprising:
a piezoelectric element;
a package containing at least the piezoelectric element; and
a vibration absorber disposed on a mounting component, configured to absorb vibration transmitted from the mounting component to the package, and supporting the package, the mounting component being a component to which the package is mounted.

2. A piezoelectric device comprising:
a piezoelectric element;
an electronic element that drives the piezoelectric element;
a first package containing the piezoelectric element and the electronic element;
a second package containing the first package; and
a vibration absorber disposed inside the second package and supporting the first package, the vibration absorber being configured to absorb vibration transmitted from the second package to the first package.

3. A piezoelectric device comprising:
a piezoelectric element;
a first package containing the piezoelectric element;
an electronic element that drives the piezoelectric element;
a second package containing the electronic element and the first package; and
a vibration absorber disposed inside the second package and supporting the first package, the vibration absorber being configured to absorb vibration transmitted from the second package to the first package.

4. The piezoelectric device according to claim 3,
wherein the first package comprises
a first base to which the piezoelectric element is mounted, and
a first lid that hermetically seals the piezoelectric element together with the first base, and
wherein the second package comprises
a second base to which the electronic element is mounted, and to which the first package is mounted with the vibration absorber interposed between the first package and the second base, and
a second lid that hermetically seals the electronic element and the first package together with the second base.

5. The piezoelectric device according to claim 3,
wherein the first package comprises
a first base comprising a first major face and a second major face opposite to the first major face,
the first major face being a major face to which the piezoelectric element is mounted,
the second major face being a major face to which the electronic element is mounted, and
a first lid that hermetically seals the piezoelectric element together with the first base, and
wherein the second package comprises
a second base to which the first package is mounted with the vibration absorber interposed between the first package and the second base, and
a second lid that hermetically seals the electronic element and the first package together with the second base.

6. The piezoelectric device according to claim 3,
wherein the first package comprises
a first base to which the piezoelectric element is mounted, and
a first lid that hermetically seals the piezoelectric element together with the first base, and
wherein the second package comprises
a second base to which the electronic element with the first package secured to the electronic element is mounted, the first package being secured to the electronic element with the vibration absorber interposed between the first package and the electronic element, and
a second lid that hermetically seals the electronic element and the first package together with the second base.

7. The piezoelectric device according to claim 1,
wherein the vibration absorber comprises a gel material.
